(19) United States
(12) Patent Application Publication
(10) Pub. No.: US 2026/0038778 A1
(43) Pub. Date: Feb. 5, 2026

(54) SUBSTRATE PROCESSING APPARATUS

(71) Applicant: Samsung Electronics Co., Ltd., Suwon-si (KR)

(72) Inventors: Jae Bin KIM, Suwon-si (KR); Seong Jun DOH, Suwon-si (KR); Chan Woo JUNG, Suwon-si (KR); Jae Won HEO, Suwon-si (KR); Jae Sung KIM, Suwon-si (KR); Jong In PARK, Suwon-si (KR); Jae Bong SIM, Suwon-si (KR); Sang-Ho LEE, Suwon-si (KR); Kang Min JEON, Suwon-si (KR); Seong Ha JEONG, Suwon-si (KR); Hae Yoon CHOI, Suwon-si (KR)

(21) Appl. No.: 19/180,946

(22) Filed: Apr. 16, 2025

(30) Foreign Application Priority Data
Aug. 2, 2024 (KR) 10-2024-0103239

(51) Int. Cl. H01J 37/32

(52) U.S. Cl. CPC H01J 37/32834; H01J 37/3244; H01J 2237/3341

(57) ABSTRACT

A processing apparatus comprising a chamber including a process space therein, a lower electrode disposed inside the chamber, an upper electrode structure disposed above the lower electrode to face the lower electrode, and an annular baffle plate disposed to surround the process space, wherein the annular baffle plate includes a first arc region and a second arc region which are disposed adjacent to each other along an annular arc and do not overlap each other, the first arc region includes a plurality of first slots, and the second arc region includes a plurality of second slots, and a first aperture ratio occupied by the first slots in the first arc region is different from a second aperture ratio occupied by the second slots in the second arc region.

### CROSS-REFERENCE TO RELATED APPLICATION

This application claims priority from Korean Patent Application No. 10-2024-0103239 filed on Aug. 2, 2024 in the Korean Intellectual Property Office, and all the benefits accruing therefrom under 35 U.S.C. 119, the contents of which in its entirety are herein incorporated by reference.

### BACKGROUND

### 1. Field of the Disclosure

The present disclosure relates to a substrate processing apparatus.

### 2. Description of the Related Art

In the semiconductor processing, various processes are performed to form features that define integrated circuits on a substrate. For example, for a deposition operation, the substrate is accommodated in a processing chamber, specific types of reactive gases are supplied to the chamber depending on the type of features to be formed, and radio frequency (RF) power is applied to generate a plasma.

The substrate is accommodated on a substrate support unit defined on a lower electrode such as an electrostatic chuck (ESC). An upper electrode such as a shower head is used to provide specific types of reactive gases into the process chamber.

A difference in etching amount may occur on a substrate due to factors such as a direction of the pattern formed on the substrate. A way for improving such etching unevenness is required.

### SUMMARY

Aspects of the present disclosure provide a substrate processing apparatus that may improve the unevenness of etching.

According to an aspect of the present disclosure, there is provided a substrate processing apparatus comprising a chamber including a process space therein, a lower electrode disposed inside the chamber, an upper electrode structure disposed above the lower electrode to face the lower electrode, and an annular baffle plate disposed to surround the process space, wherein the annular baffle plate includes a first arc region and a second arc region which are disposed adjacent to each other along an annular arc and do not overlap each other, the first arc region includes a plurality of first slots, and the second arc region includes a plurality of second slots, and a first aperture ratio occupied by the first slots in the first arc region is different from a second aperture ratio occupied by the second slots in the second arc region.

According to an aspect of the present disclosure, there is provided a substrate processing apparatus comprising a chamber including a process space therein, a lower electrode disposed inside the chamber, an upper electrode structure disposed above the lower electrode to face the lower electrode, and an annular baffle plate disposed to surround the process space, wherein the annular baffle plate includes a first arc region and a second arc region which are disposed adjacent to each other along an annular arc and do not overlap each other, the first arc region includes a plurality of slots, and the second arc region includes no slots.

According to an aspect of the present disclosure, there is provided a substrate processing apparatus comprising a chamber including a process space therein, a lower electrode disposed inside the chamber, an upper electrode structure which is disposed above the lower electrode to face the lower electrode, and includes an upper electrode and a shower head, and an annular baffle plate disposed to surround the process space, wherein the shower head includes a first region having first gas holes, and a second region having second gas holes, the number of first gas holes is different from the number of second gas holes, the annular baffle plate has a shape in which an upper horizontal part, a vertical part, and a lower horizontal part are connected, the lower horizontal part includes a first arc region and a second arc region which are disposed adjacent to each other along an annular arc and do not overlap each other, the first arc region is greater than the second arc region, the first arc region includes a plurality of first slots, the second arc region includes a plurality of second slots, and a first aperture ratio occupied by the first slots in the first arc region is greater than a second aperture ratio occupied by the second slots in the second arc region.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail illustrative embodiments thereof with reference to the attached drawings, in which:

FIG. 1 is a side view for explaining a substrate processing apparatus according to some embodiments of the present disclosure.

FIG. 2 is a perspective view for explaining a baffle plate according to some embodiments of the present disclosure.

FIG. 3 is a plan view for explaining the baffle plate according to some embodiments of the present disclosure.

FIG. 4 is a perspective view of the baffle plate in which the region P1 of FIG. 2 is enlarged to explain the baffle plate according to some embodiments of the present disclosure.

FIG. 5 is a cross-sectional view for explaining a region of a substrate according to some embodiments of the present disclosure.

FIG. 6 is a perspective view for explaining an upper electrode structure according to some embodiments of the present disclosure.

FIG. 7 is a plan view for explaining the upper electrode structure according to some embodiments of the present disclosure.

FIG. 8 is a cross-sectional view representing a region H1 of FIG. 7 to explain the upper electrode according to some embodiments of the present disclosure.

FIG. 9 is a cross-sectional view representing a region H2 of FIG. 7 to explain the upper electrode according to some embodiments of the present disclosure.

FIG. 10 is a perspective view of a baffle plate in which the region P1 of FIG. 2 is enlarged to explain the baffle plate according to another embodiment of the present disclosure.

FIG. 11 is a perspective view of a baffle plate according to another embodiment of the present disclosure, in which the region P1 of FIG. 2 is enlarged.

FIG. 12 is a perspective view of a baffle plate according to another embodiment of the present disclosure, in which the region P1 of FIG. 2 is enlarged.

FIG. 13 is a perspective view of a baffle plate according to another embodiment of the present disclosure, in which the region P1 of FIG. 2 is enlarged.

FIG. 14 is a perspective view of a baffle plate according to another embodiment of the present disclosure, in which the region P1 of FIG. 2 is enlarged.

FIG. 15 is a perspective view for explaining a baffle plate according to some embodiments of the present disclosure.

FIG. 16 is a plan view for explaining the baffle plate according to some embodiments of the present disclosure.

FIG. 17 is a perspective view of the baffle plate according to some embodiments of the present disclosure, in which a region P2 of FIG. 15 is enlarged.

FIG. 18 is a cross-sectional view showing a region H1 of FIG. 7 to explain an upper electrode according to another embodiment of the present disclosure.

FIG. 19 is a cross-sectional view showing a region H2 of FIG. 7 to explain an upper electrode according to another embodiment of the present disclosure.

FIG. 20 is a perspective view for explaining a baffle plate according to another embodiment of the present disclosure.

FIG. 21 is a plan view for explaining the baffle plate according to another embodiment of the present disclosure.

### DETAILED DESCRIPTION OF THE EMBODIMENTS

Although terms such as first and second are used to describe various elements or components in the present specification, these elements or components are not limited by these terms. These terms are only used to distinguish a single element or component from other elements or components. Therefore, a first element or component referred to below may be a second element or component within the technical idea of the present disclosure.

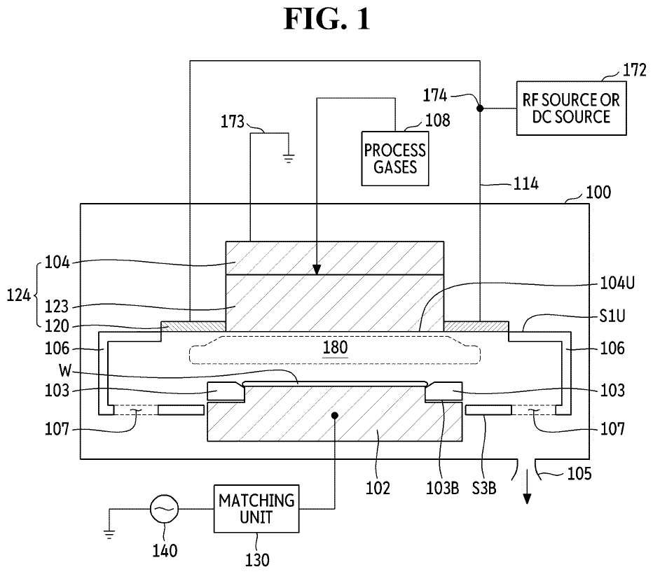

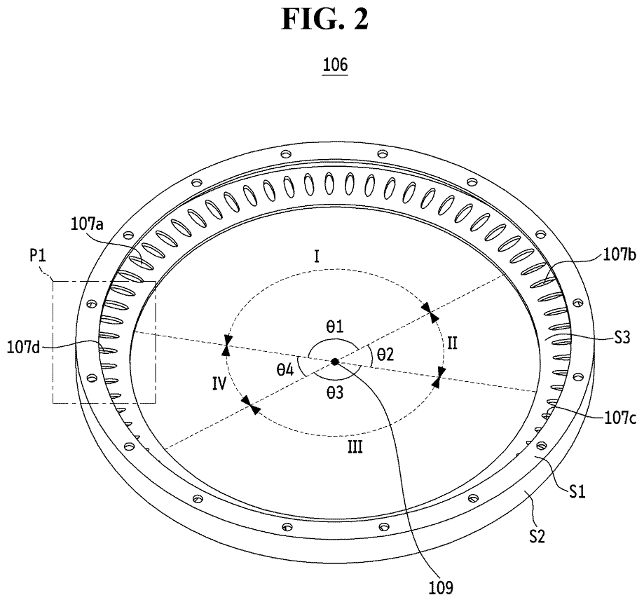

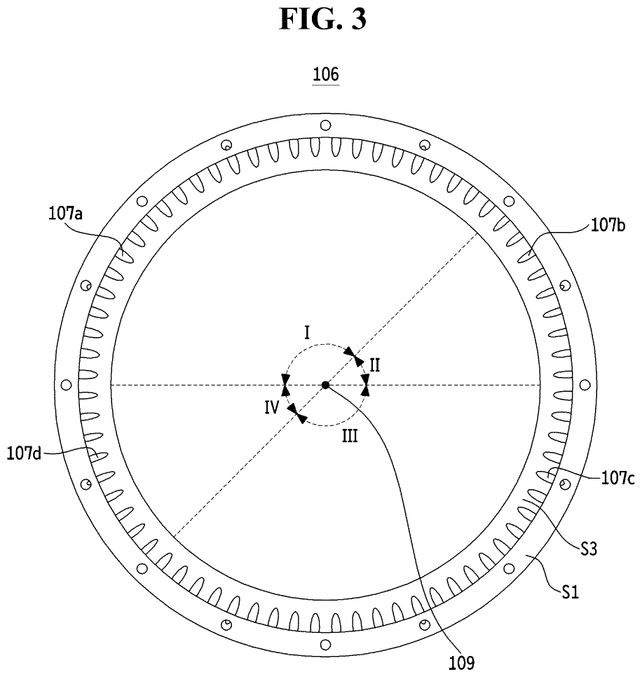

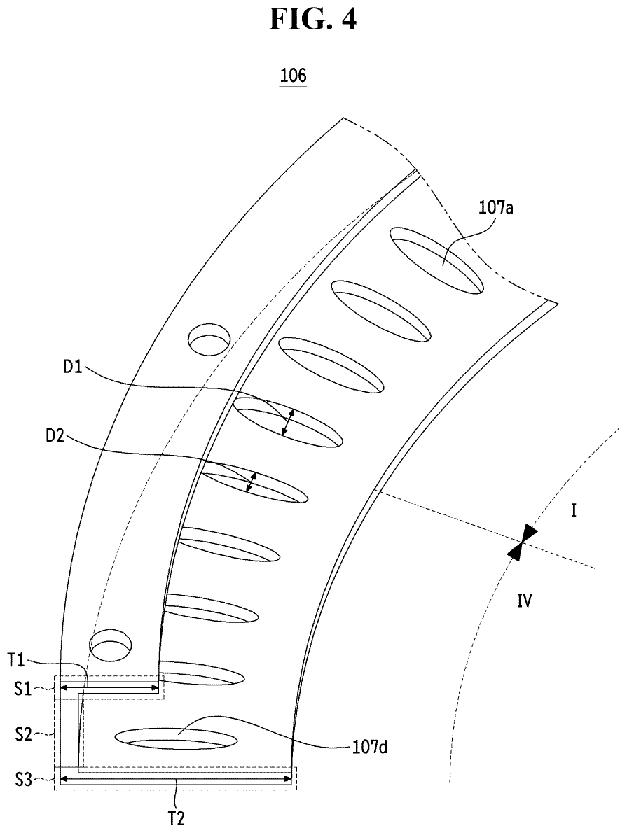

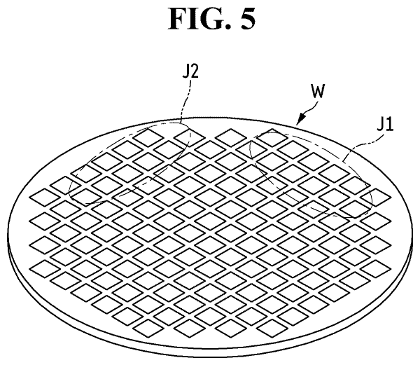

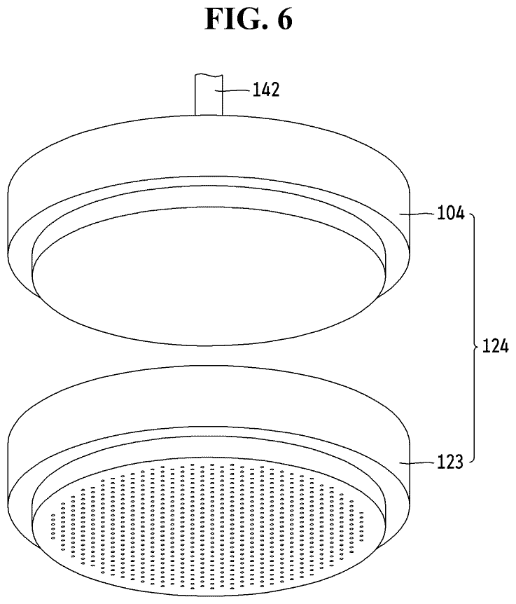

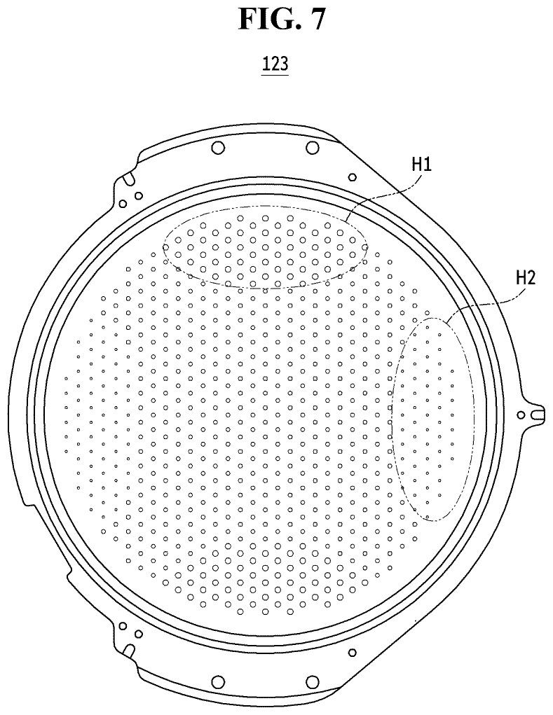

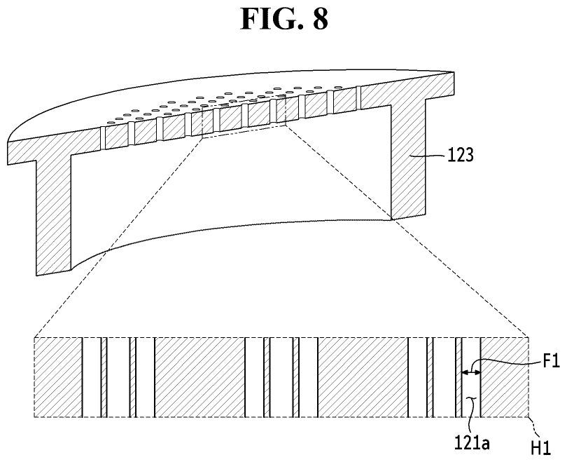

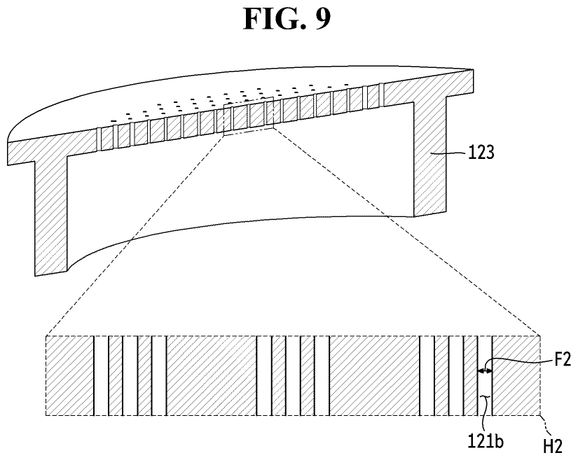

FIG. 1 is a side view for explaining a substrate processing apparatus according to some embodiments of the present disclosure. FIG. 2 is a perspective view for explaining a baffle plate according to some embodiments of the present disclosure. FIG. 3 is a plan view for explaining the baffle plate according to some embodiments of the present disclosure. FIG. 4 is a perspective view of the baffle plate in which the region P1 of FIG. 2 is enlarged to explain the baffle plate according to some embodiments of the present disclosure. FIG. 5 is a cross-sectional view for explaining a region of a substrate according to some embodiments of the present disclosure. FIG. 6 is a perspective view for explaining an upper electrode structure according to some embodiments of the present disclosure. FIG. 7 is a plan view for explaining the upper electrode structure according to some embodiments of the present disclosure. FIG. 8 is a cross-sectional view representing a region H1 of FIG. 7 to explain the upper electrode according to some embodiments of the present disclosure. FIG. 9 is a cross-sectional view representing a region H2 of FIG. 7 to explain the upper electrode according to some embodiments of the present disclosure.

Referring to FIGS. 1 to 9, the substrate processing apparatus according to some embodiments of the present disclosure may include a chamber 100, a lower electrode 102, an edge ring 103, an upper electrode structure 124, a baffle plate 106, a process gas tank 108, and a vacuum port 105.

The chamber 100 may provide a process space 180 for processing a substrate W. For example, a plasma may be provided inside the chamber 100 to perform an etching process.

The lower electrode 102 may be disposed inside the chamber 100. For example, the lower electrode 102 may be disposed at a lower part of the chamber 100. The lower electrode 102 may be a chuck. For example, the lower electrode 102 may be an electrostatic chuck or a vacuum chuck. The lower electrode 102 may have an upper face onto which the substrate W is loaded. The lower electrode 102 may be connected to a radio frequency (RF) power source 140 through a matching unit 130. For example, the radio frequency power source 140 may operate at frequencies such as 13.56 MHZ, 60 MHz, 27 MHz, 2 MHZ, and 400 kHz. For example, the radio frequency power source 140 may be one of a plurality of radio frequency power sources that may simultaneously operate at different frequencies.

The edge ring 103 may be disposed on the lower electrode 102. For example, the edge ring 103 may have an annular shape and may be disposed to surround a surface above the lower electrode 102 on which the substrate W is disposed. The edge ring 103 may include quartz, sapphire, glass, ceramic, metal or a combination thereof.

The upper electrode structure 124 may be disposed inside the chamber 100 to face the lower electrode 102. The upper electrode structure 124 may include a gas inlet 142, an inner upper electrode 104, an outer upper electrode 120, and a shower head 123. The inner upper electrode 104 and the shower head 123 may be disposed to come into contact with each other. The inner upper electrode 104 may be connected and coupled to a ground 173. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The inner upper electrode 104 may be disposed at the center of the upper electrode structure 124. The inner upper electrode 104 may be provided with a process gas from a process gas tank 108 through the gas inlet 142, and may bring the process gas supplied into the chamber 100 into a plasma state.

The outer upper electrode 120 may be disposed to surround the shower head 123. The outer upper electrode 120 may include, for example, polysilicon. The outer upper electrode 120 may be electrically connected to an RF source or a DC source 172. The outer upper electrode 120 may be electrically coupled to the RF or DC source 172 through a plurality of power rods 114. The plurality of power rods 114 may be electrically connected together, and thus may be connected to the RF or DC source 172 through the connecting node 174.

The shower head 123 may include a plurality of gas holes 121a and 121b. The shower head 123 may include a first region H1 and a second region H2. A width F1 of the gas hole 121a disposed in the first region H1 of the shower head 123 may be different from a width F2 of the gas hole 121b disposed in the second region H2 of the shower head 123. For example, the width F1 of the gas hole 121a disposed in the first region H1 of the shower head 123 may be greater than the width F2 of the gas hole 121b disposed in the second region H2 of the shower head 123. In this case, the amount of gas provided to the first region H1 may be larger than the amount of gas provided to the second region H2.

The baffle plate 106 may be disposed to surround the process space 180. For example, portions of the baffle plate 106 may be disposed between the lower electrode 102 and the inner upper electrode 104. The baffle plate 106 uniformly exhausts unreacted gases and polymers inside the chamber 100 to the lower part of the chamber 100, and, thus, uniform etching may occur on the wafer. The process gas, the impurities and the like discharged to the outside of the process space 180 through the baffle plate 106 may be discharged to the outside of the chamber 100 through a vacuum port 105 to be described below.

The time at which plasma resides in the process space 180 changes by the baffle plate 106, and thus, the etching amount of the substrate may be adjusted. For example, when an aperture ratio of the slots disposed inside the baffle plate 106 is large, the etching amount of the substrate may be larger than a case where the aperture ratio is small. As another example, when the aperture ratio of the slots disposed in the baffle plate 106 is small, the etching amount of the substrate may be smaller than the case where the aperture ratio is large. Therefore, the size of the slots of the baffle plate 106 may be adjusted to adjust the etching amount of the substrate W inside the chamber 100.

The baffle plate 106 may have an annular shape. The baffle plate 106 may have a form in which, for example, a ceramic such as Y₂O₃ is coated with an aluminum member. The baffle plate 106 may include a lower horizontal part S3, an upper horizontal part S1, and a vertical part S2 that connects the lower horizontal part S3 and the upper horizontal part S1. The lengths of the upper horizontal part S1 and the lower horizontal part S3 may be different from each other. For example, a length T1 of the upper horizontal part S1 may be shorter than a length T2 of the lower horizontal part S3.

A lower face S3B of the lower horizontal part S3 of the baffle plate 106 may be disposed at a lower position than the lower face 103B of the edge ring 103, but the embodiment of the present disclosure is not limited thereto. For example, although not illustrated, the lower face S3B of the lower horizontal part S3 of the baffle plate 106 may be disposed at a higher position than the lower face 103B of the edge ring 103.

An upper face SIU of the upper horizontal part S1 of the baffle plate 106 may be disposed at the same height as the lower face 104U of the inner upper electrode 104, but the embodiment of the present disclosure is not limited thereto. For example, although not illustrated, the upper face SIU of the upper horizontal part S1 of the baffle plate 106 may be disposed at a different height from the lower face 104U of the inner upper electrode 104. That is, the upper face SIU of the upper horizontal part S1 of the baffle plate 106 may be disposed to be lower or higher than the lower face 104U of the inner upper electrode 104.

The lower horizontal part S3 of the baffle plate 106 may include a first arc region I, a second arc region II, a third arc region III, and a fourth arc region IV that do not overlap each other. The first arc region I and the third arc region III may be disposed to face each other. The second arc region II and the fourth arc region IV may be disposed to face each other. The range of the first arc region I and the range of the third arc region III may be the same, and the range of the second arc region II and the range of the third arc region III may be the same.

The first arc region I may have a first central angle θ1 with respect to the center 109 of the annular baffle plate 106. The second arc region II may have a second central angle θ2 with respect to the center 109. The third arc region III may have a third central angle θ3 with respect to the center 109. The fourth arc region IV may have a fourth central angle θ4 with respect to the center 109.

The first central angle θ1 may have the same magnitude as the third central angle θ3. The second central angle θ2 may have the same magnitude as the fourth central angle θ4. The first central angle θ1 may be greater than the second central angle θ2. The third central angle 03 may be greater than the fourth central angle θ4. The sum of the first central angle θ1 and the second central angle θ2 may be 180°. The sum of the third central angle θ3 and the fourth central angle θ4 may be 180°.

A plurality of first slots 107a may be disposed in the first arc region I. The first slots 107a may have a first aperture ratio. A plurality of second slots 107b may be disposed in the second arc region II. The second slots 107b may have a second aperture ratio. A plurality of third slots 107c may be disposed in the third arc region III. The third slots 107c may have a third aperture ratio. A plurality of fourth slots 107d may be disposed in the fourth arc region IV. The fourth slots 107d may have a fourth aperture ratio. Although all the openings of the first to fourth slots 107a, 107b, 107c, and 107d are shown as oval, the embodiment of the present disclosure is not limited thereto. As another example, the first to fourth slots 107a, 107b, 107c, and 107d may have circular or rectangular openings. The first to fourth slots 107a, 107b, 107c, and 107d may be collectively referenced as slots 107 herein.

The first aperture ratio and the third aperture ratio are different from the second aperture ratio and the fourth aperture ratio, respectively. For example, the first aperture ratio may be greater than the second aperture ratio. The third aperture ratio may be greater than the fourth aperture ratio. The first aperture ratio may be the same as the third aperture ratio, and the second aperture ratio may be the same as the fourth aperture ratio, but the embodiment of the present disclosure is not limited thereto. As another example, the first aperture ratio may be different from the third aperture ratio, and the second aperture ratio may be different from the fourth aperture ratio. The sum of the first aperture ratio and the third aperture ratio may be greater than the sum of the second aperture ratio and the fourth aperture ratio.

The number of the first slots 107a disposed in the first arc region I of the baffle plate 106 may be the same as the number of the third slots 107c disposed in the third arc region III. The number of the second slots 107b disposed in the second arc region II of the baffle plate 106 may be the same as the number of the fourth slots 107d disposed in the fourth arc region IV.

In FIG. 4, for convenience of explanation, only the first arc region I and the fourth arc region IV are shown, but each of the second arc region II and the third arc region III may include the same slot structure as the fourth arc region IV and the first arc region I. Hereinafter, the first slot 107a of the first arc region I and the fourth slot 107d of the fourth arc region IV will be compared and explained.

A width D1 of the first slot 107a of the first arc region I may be greater than a width D2 of the fourth slot 107d of the fourth arc region IV. Therefore, the first aperture ratio (e.g., size) of the first slot 107a may be greater than the fourth aperture ratio (e.g., size) of the fourth slot 107d.

The process gas tank 108 may provide process gas to the inside of the chamber 100. For example, when an etching process is performed inside the chamber 100, the process gas tank 108 may store at least one of fluorocarbon, chlorine, bromine, oxygen, argon, nitrogen, and helium. The process gas provided by the process gas tank 108 may form a plasma, and be supplied to the inside of the chamber 100.

The substrate W may be provided into the chamber 100 such that a process may be performed on the substrate W. The substrate W may include a first portion J1 and a second portion J2. The process may be performed non-uniformly in the first portion J1 and the second portion J2 of the substrate W. For example, the first portion J1 of the substrate W may be etched at an etching amount less than the second portion J2. In other words, unevenness in the etching amount may occur inside the substrate W.

The uniformity of the etching process may not be maintained due to various factors of the process. For example, the etching amount may differ for each region (i.e., portion) of the substrate W because the direction of the pattern formed on the substrate W is different from the direction in which the plasma is provided. As another example, the etching amount may differ for each region of the substrate W due to the flow of plasma provided into the chamber 100.

With respect to the present application, when the substrate W is loaded onto the lower electrode 102, the first portion J1 of the substrate W may be loaded to be disposed below the first region H1 of the shower head 123. The second portion J2 of the substrate W may be loaded to be disposed below the second region H2 of the shower head 123. Because the width F1 of the gas hole 121a disposed in the first region H1 of the shower head 123 is greater than the width F2 of the gas hole 121b disposed in the second region H2 of the shower head 123, the etching amount of the first portion J1 may be larger than the etching amount of the second portion J2. As a result, according to aspects of the present application, the etching amounts of the first portion J1 and the second portion J2 may be adjusted uniformly.

When the substrate W is loaded onto the lower electrode 102, the first portion J1 of the substrate W may be loaded to correspond to (e.g., disposed within or overlap with) the first arc region I of the baffle plate 106. The second portion J2 of the substrate W may be loaded to correspond (e.g., disposed within or overlap with) to the second arc region II of the baffle plate 106. Because the first aperture ratio is higher than the second aperture ratio, the etching amount of the first portion J1 may be larger than the etching amount of the second portion J2. As a result, the etching amounts of the first portion J1 and the second portion J2 may be uniformly adjusted.

The vacuum port 105 may be disposed at the lower part of the chamber 100. By-products formed in the process space 180 may be discharged through the vacuum port 105.

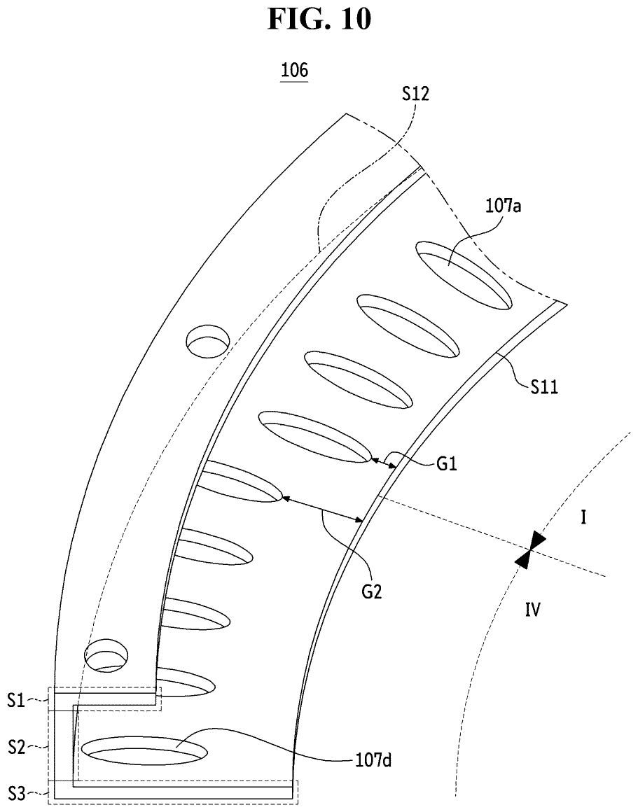

FIG. 10 is a perspective view of a baffle plate in which the region P1 of FIG. 2 is enlarged to explain the baffle plate according to another embodiment of the present disclosure. For convenience of explanation, FIG. 10 will be mainly explained on the basis of the differences from those explained using FIGS. 1 to 9. For reference, a baffle plate 106 shown in FIG. 10 may correspond to the baffle plate 106 of FIG. 1.

Although only the first arc region I and the fourth arc region IV are shown in FIG. 10 for convenience of explanation, each of the second arc region II and the third arc region III may include the same slot structure as the fourth arc region IV and the first arc region I.

Referring to FIG. 10, the lower horizontal part S3 of the baffle plate 106 may include an inner circumferential part S11 and an outer circumferential part S12. The inner circumferential part S11 may include a short circumference of the lower horizontal part S3, and the outer circumferential part S12 may include a long circumference of the lower horizontal part S3.

A distance G1 between the first slot 107a disposed in the first arc region I and the inner circumferential part S11 may be different from a distance G2 between the fourth slot 107d disposed in the fourth arc region IV and the inner circumferential part S11. For example, the distance G1 between the first slot 107a disposed in the first arc region I and the inner circumferential part S11 may be smaller than the distance G2 between the fourth slot 107d disposed in the fourth arc region IV and the inner circumferential part S11. For example, the first slot 107a may be disposed to be closer to the inner circumferential part S11 than the fourth slot 107d, and thus closer to the substrate (see W of FIG. 5) than the fourth slot 107d.

When the substrate (see W of FIG. 5) is loaded onto the lower electrode (see 102 of FIG. 1), the first portion J1 of the substrate W may be loaded to correspond to the first arc region I of the baffle plate 106. The second portion J2 of the substrate W may be loaded to correspond to the fourth arc region IV of the baffle plate 106. The first slot 107a of the first arc region I may be disposed to be closer to the substrate W than the fourth slot 107d of the fourth arc region IV, and the etching amount of the first portion J1 may be greater than the etching amount of the second portion J2. As a result, the etching amounts of the first portion J1 and the second portion J2 may be uniformly adjusted.

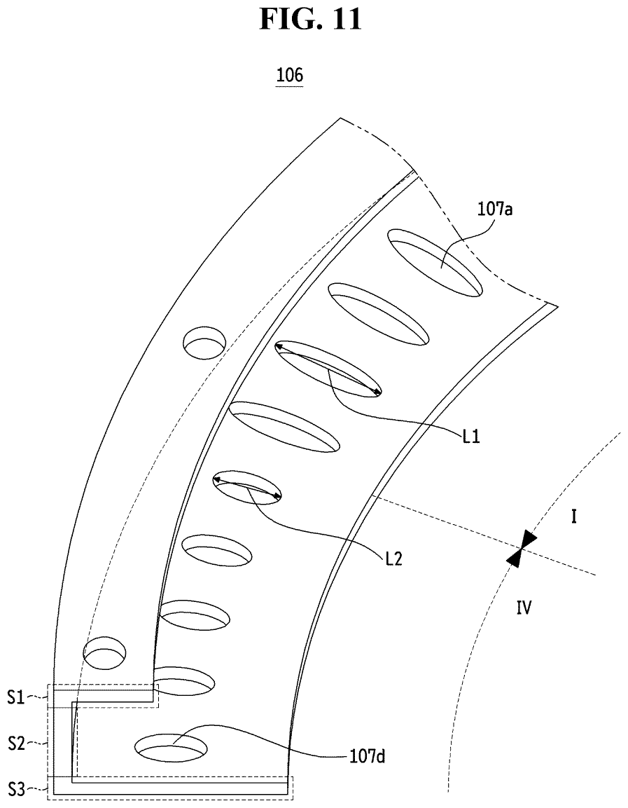

FIG. 11 is a perspective view of a baffle plate according to another embodiment of the present disclosure, in which the region P1 of FIG. 2 is enlarged. For convenience of explanation, FIG. 11 will be explained on the basis of the differences from those described using FIGS. 1 to 9. For reference, the baffle plate 106 shown in FIG. 11 may correspond to the baffle plate 106 of FIG. 1. In FIG. 11, although only the first arc region I and the fourth arc region IV are shown for convenience of explanation, each of the second arc region II and the third arc region III may include the same slot structure as the fourth arc region IV and the first arc region I.

Referring to FIG. 11, a longitudinal length L1 of the first slot 107a disposed in the first arc region I may be different from a longitudinal length L2 of the fourth slot 107d disposed in the fourth arc region IV. For example, the longitudinal length L1 of the first slot 107a disposed in the first arc region I may be longer than the longitudinal length L2 of the fourth slot 107d disposed in the fourth arc region IV.

When the substrate (see W of FIG. 5) is loaded onto the lower electrode (see 102 of FIG. 1), the first portion J1 of the substrate W may be loaded to correspond to the first arc region I of the baffle plate 106. The second portion J2 of the substrate W may be loaded to correspond to the fourth arc region IV of the baffle plate 106. Since the first aperture ratio of the first slot 107a is greater than the fourth aperture ratio of the fourth slot 107d, the etching amount of the first portion J1 may be larger than the etching amount of the second portion J2. As a result, the etching amounts of the first portion J1 and the second portion J2 may be uniformly adjusted.

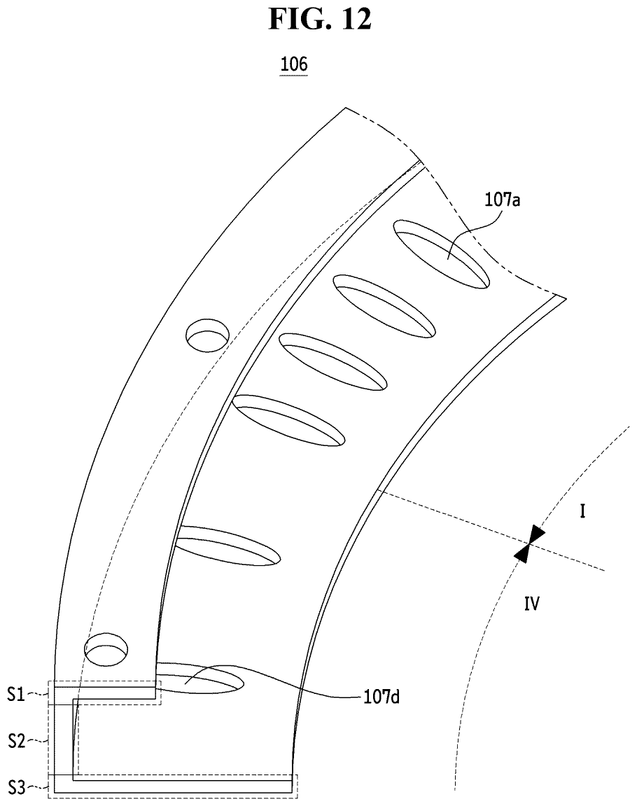

FIG. 12 is a perspective view of a baffle plate according to another embodiment of the present disclosure, in which the region P1 of FIG. 2 is enlarged. For convenience of explanation, FIG. 12 will be explained on the basis of differences from those described using FIGS. 1 to 9. For reference, the baffle plate 106 shown in FIG. 12 may correspond to the baffle plate 106 of FIG. 1. For convenience of explanation, FIG. 12 shows only the first arc region I and the fourth arc region IV, but each of the second arc region II and the third arc region III may include the same slot structure as the fourth arc region IV and the first arc region I.

Referring to FIG. 12, the number of first slots 107a disposed in the first arc region I may be different from the number of fourth slots 107d disposed in the fourth arc region IV. For example, the number of first slots 107a disposed in the first arc region I may be greater than the number of fourth slots 107d disposed in the fourth arc region IV. As an example, when fifty first slots 107a are disposed in the first arc region I, twenty fourth slots 107d may be disposed in the fourth arc region IV. The first aperture ratio of the first slots 107a and the fourth aperture ratio of the fourth slots 107d may be the same, but the embodiment of the present disclosure is not limited thereto.

When the substrate (see W of FIG. 5) is loaded onto the lower electrode (see 102 of FIG. 1), the first portion J1 of the substrate W may be loaded to correspond to the first arc region I of the baffle plate 106. The second portion J2 of the substrate W may be loaded to correspond to the fourth arc region IV of the baffle plate 106. Since the number of the first slots 107a is greater than the fourth number of the fourth slots 107d, the etching amount of the first portion J1 may be greater than the etching amount of the second portion J2. As a result, the etching amounts of the first portion J1 and the second portion J2 may be adjusted uniformly.

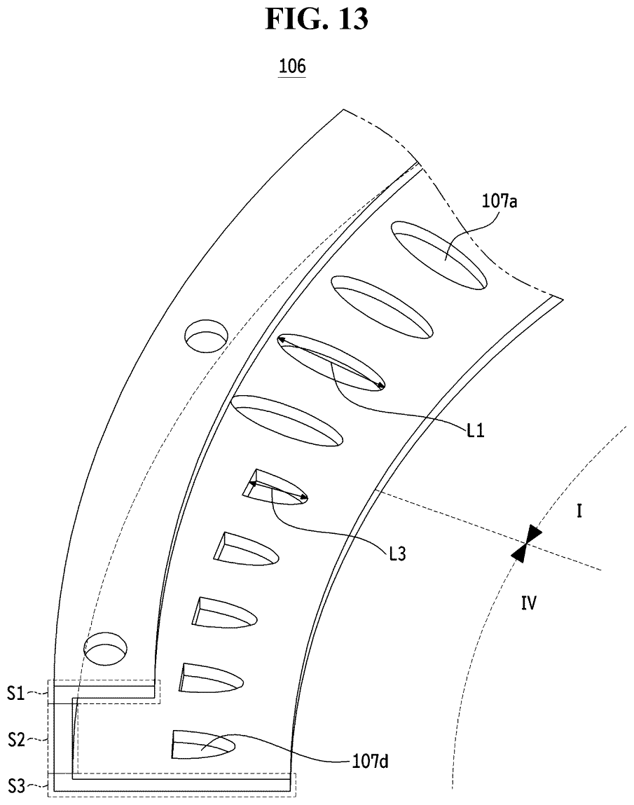

FIG. 13 is a perspective view of a baffle plate according to another embodiment of the present disclosure, in which the region P1 of FIG. 2 is enlarged. For convenience of explanation, FIG. 13 will be mainly explained on the basis of differences from those described using FIGS. 1 to 9. For reference, the baffle plate 106 shown in FIG. 13 may correspond to the baffle plate 106 of FIG. 1. For convenience of explanation, FIG. 13 shows only the first arc region I and the fourth arc region IV, but each of the second arc region II and the third arc region III may include the same slot structure as the fourth arc region IV and the first arc region I.

Referring to FIG. 13, the shape of the first slot 107a disposed in the first arc region I may be different from the shape of the fourth slot 107d disposed in the fourth arc region IV. For example, the first slot 107a has an elliptical shape, and meanwhile, the fourth slot 107d may have a shape including only half of an ellipse. In this case, the longitudinal length L1 of the first slot 107a may be different from the longitudinal length L3 of the fourth slot 107d. For example, the longitudinal length L1 of the first slot 107a may be longer than the longitudinal length L3 of the fourth slot 107d.

When the substrate (see W of FIG. 5) is loaded onto the lower electrode (see 102 of FIG. 1), the first portion J1 of the substrate W may be loaded to correspond to the first arc region I of the baffle plate 106. The second portion J2 of the substrate W may be loaded to correspond to the fourth arc region IV of the baffle plate 106. Since the first aperture ratio of the first slot 107a is greater than the fourth aperture ratio of the fourth slot 107d, the etching amount of the first portion J1 may be larger than the etching amount of the second portion J2. As a result, the etching amounts of the first portion J1 and the second portion J2 may be adjusted uniformly.

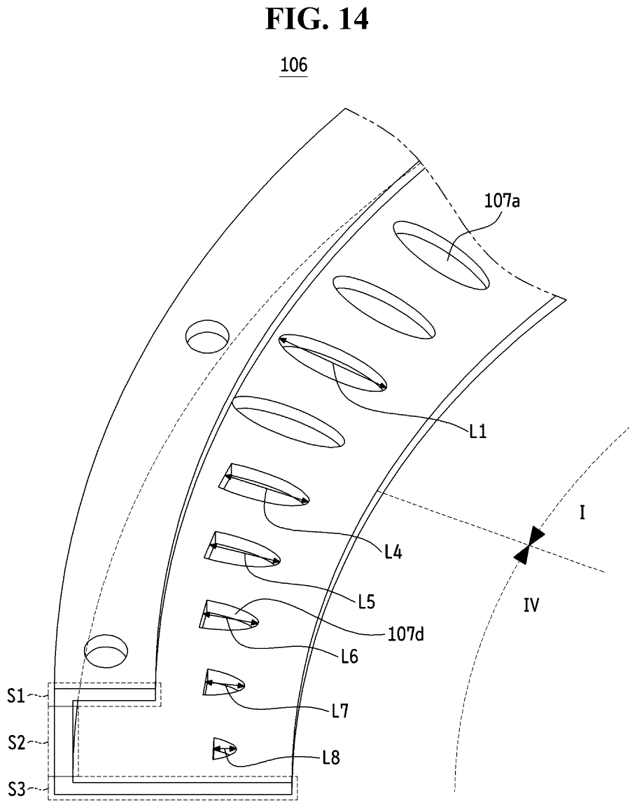

FIG. 14 is a perspective view of a baffle plate according to another embodiment of the present disclosure, in which the region P1 of FIG. 2 is enlarged. For convenience of explanation, FIG. 14 will be mainly explained on the basis of differences from those described using FIGS. 1 to 9. For reference, the baffle plate 106 shown in FIG. 14 may correspond to the baffle plate 106 of FIG. 1. For convenience of explanation, FIG. 14 shows only the first arc region I and the fourth arc region IV, but each of the second arc region II and the third arc region III may include the same slot structure as the fourth arc region IV and the first arc region I.

Referring to FIG. 14, the shape of the fourth slot 107d disposed in the fourth arc region IV may be various. Also, the shape of the first slot 107a disposed in the first arc region I may be different from the shape of the fourth slot 107d disposed in the fourth arc region IV. For example, the first slot 107a may have an elliptical shape, and meanwhile, the fourth slot 107d may have a shape including only a part of an ellipse. Also, the plurality of fourth slots 107d may include shapes different from each other. In such a case, the longitudinal length L1 of the first slot 107a may be different from the longitudinal lengths L4, L5, L6, L7, and L8 of the fourth slots 107d. For example, the longitudinal length L1 of the first slot 107a may be longer than the longitudinal lengths L4, L5, L6, L7, and L8 of the fourth slot 107d.

When the substrate (see W of FIG. 5) is loaded onto the lower electrode (see 102 of FIG. 1), the first portion J1 of the substrate W may be loaded to correspond to the first arc region I of the baffle plate 106. The second portion J2 of the substrate W may be loaded to correspond to the fourth arc region IV of the baffle plate 106. Since the first aperture ratio of the first slot 107a is greater than the fourth aperture ratio of the fourth slot 107d, the etching amount of the first portion J1 may be larger than the etching amount of the second portion J2. As a result, the etching amounts of the first portion J1 and the second portion J2 may be uniformly adjusted.

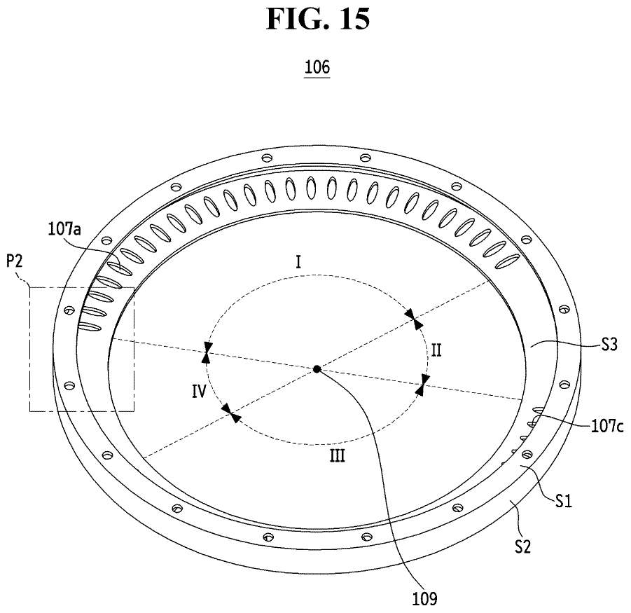

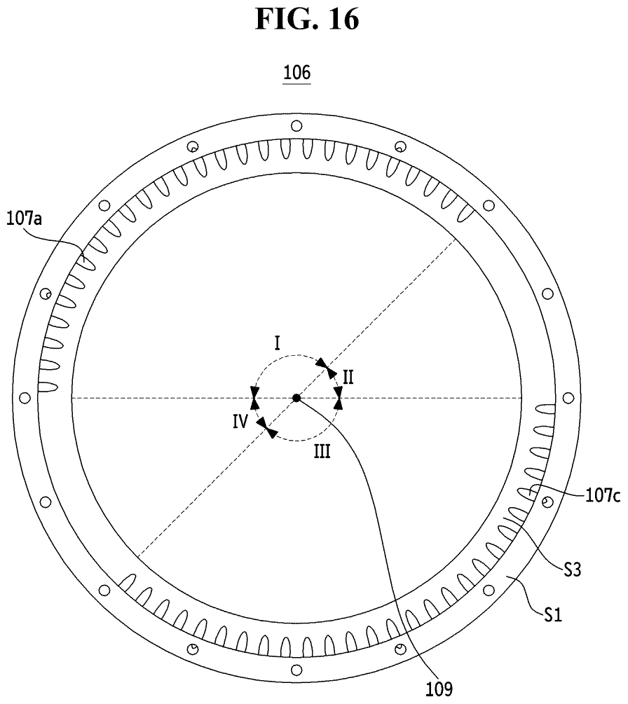

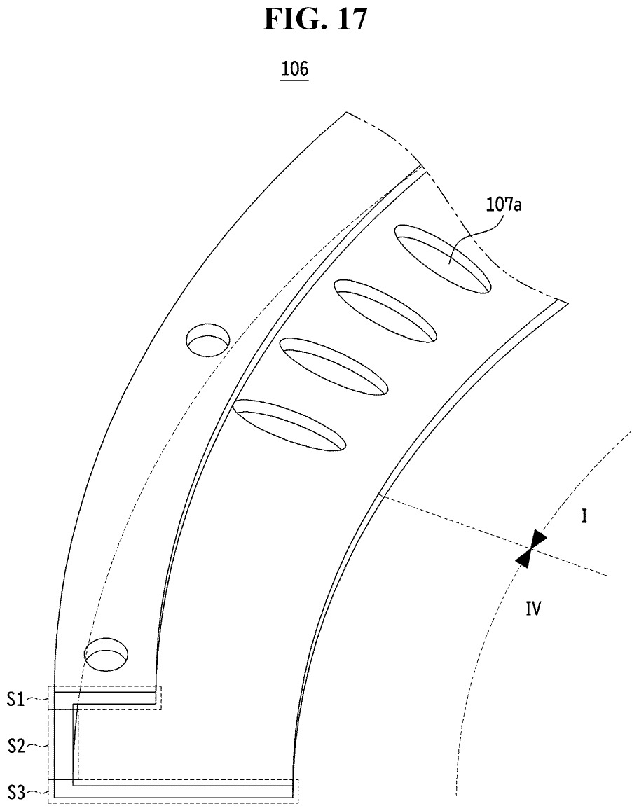

FIG. 15 is a perspective view for explaining a baffle plate according to some embodiments of the present disclosure. FIG. 16 is a plan view for explaining the baffle plate according to some embodiments of the present disclosure. FIG. 17 is a perspective view of the baffle plate according to some embodiments of the present disclosure, in which a region P2 of FIG. 15 is enlarged. For convenience of explanation, FIGS. 15 to 17 will be explained on the basis of differences from those described using FIGS. 1 to 9. For reference, the baffle plate 106 shown in FIGS. 15 to 17 may correspond to the baffle plate 106 in FIG. 1.

Referring to FIGS. 15 to 17, the lower horizontal part S3 of the baffle plate 106 according to another embodiment of the present disclosure may include a first arc region I, a second arc region II, a third arc region III, and a fourth arc region IV. A plurality of first slots 107a may be disposed in the first arc region I. No slot(s) may be disposed in the second arc region II. A plurality of third slots 107c may be disposed in the third arc region III. No slot(s) may be disposed in the fourth arc region IV.

In FIG. 17, for convenience of explanation, only the first arc region I and the fourth arc region IV are shown, but each of the second arc region II and the third arc region III may include the same slot structure as the fourth arc region IV and the first arc region I. Hereinafter, the first slot 107a of the first arc region I and the fourth slot 107d of the fourth arc region IV will be compared and explained.

When the substrate (see W of FIG. 5) is loaded onto the lower electrode (see 102 of FIG. 1), the first portion J1 of the substrate W may be loaded to correspond to the first arc region I of the baffle plate 106. The second portion J2 of the substrate W may be loaded to correspond to the second arc region II of the baffle plate 106. The first slot is disposed only in the first arc region I, and thus, the etching amount of the first portion J1 may be larger than the etching amount of the second portion J2. As a result, the etching amounts of the first portion J1 and the second portion J2 may be adjusted uniformly.

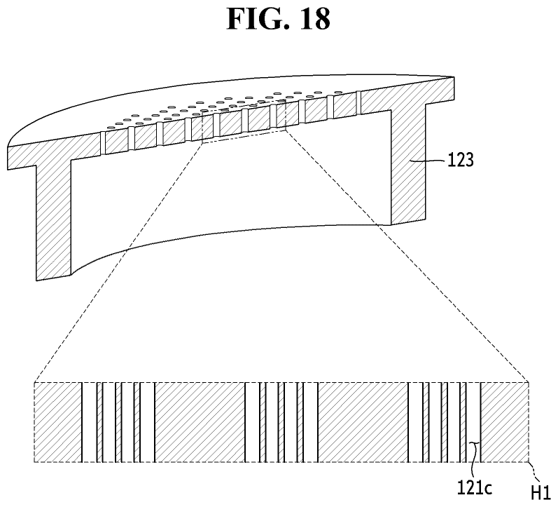

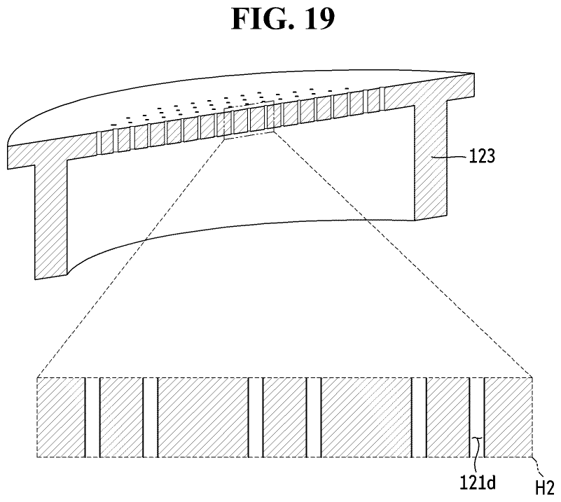

FIG. 18 is a cross-sectional view showing a region H1 of FIG. 7 to explain an upper electrode according to another embodiment of the present disclosure. FIG. 19 is a cross-sectional view showing a region H2 of FIG. 7 to explain an upper electrode according to another embodiment of the present disclosure. FIGS. 18 and 19 will be explained on the basis of differences from those described using FIGS. 1 to 9. For reference, the baffle plate 106 shown in FIGS. 18 and 19 may correspond to the baffle plate 106 of FIG. 1.

Referring to FIGS. 18 and 19, the shower head 123 according to another embodiment of the present disclosure may include a first region H1 and a second region H2. The number of gas holes 121c disposed in the first region H1 of the shower head 123 may be different from the number of gas holes 121d disposed in the second region H2 of the shower head 123. For example, the number of gas holes 121c disposed in the first region H1 of the shower head 123 may be larger than the number of gas holes 121d disposed in the second region H2 of the shower head 123. In such a case, the amount of gas provided to the first region H1 may be larger than the amount of gas provided to the second region H2.

When the substrate W is loaded onto the lower electrode 102, the first portion J1 of the substrate W may be loaded to be disposed below the first region H1 of the shower head 123. The second portion J2 of the substrate W may be loaded to be disposed below the second region H2 of the shower head 123. Because the number of gas holes 121c disposed in the first region H1 of the shower head 123 is larger than the number of gas holes 121d disposed in the second region H2 of the shower head 123, the etching amount of the first portion J1 may be larger than the etching amount of the second portion J2. As a result, the etching amounts of the first portion J1 and the second portion J2 may be uniformly adjusted.

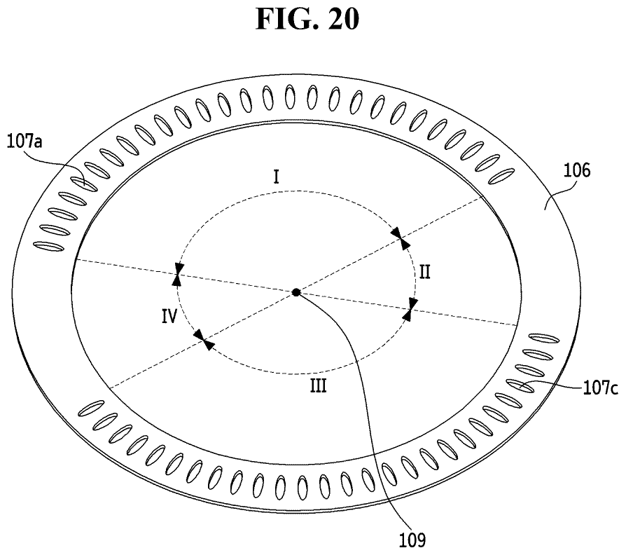

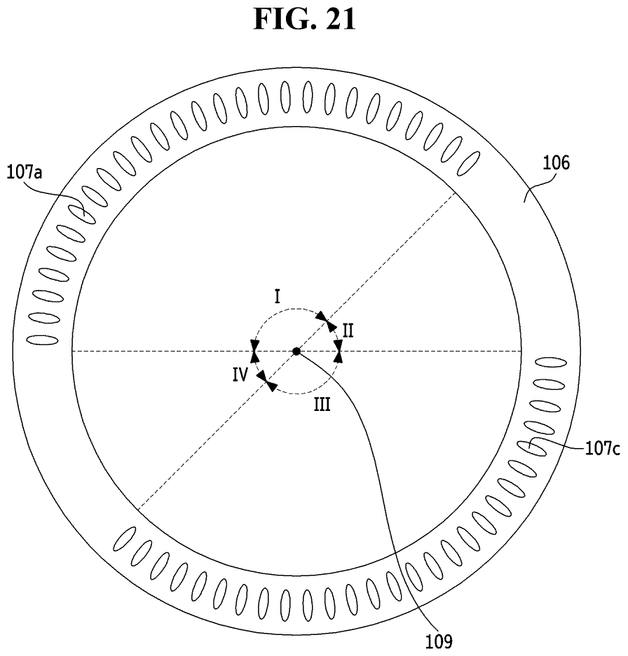

FIG. 20 is a perspective view for explaining a baffle plate according to another embodiment of the present disclosure. FIG. 21 is a plan view for explaining the baffle plate according to another embodiment of the present disclosure. For convenience of explanation, FIGS. 20 and 21 will be explained on the basis of the differences from those described using FIGS. 1 to 9. For reference, the baffle plate 106 shown in FIGS. 20 and 21 may correspond to the baffle plate 106 of FIG. 1.

Referring to FIGS. 20 and 21, the baffle plate 106 according to another embodiment of the present disclosure may have an annular shape. The baffle plate 106 may have a flat plate shape without including a horizontal part and/or a vertical part. The lower face 106B of the baffle plate 106 may be disposed to be lower than the lower face 103B of the edge ring 103, but the embodiment of the present disclosure is not limited thereto. As another example, the lower face 106B of the baffle plate 106 may be disposed to be higher than the lower face 103B of the edge ring 103.

The baffle plate 106 may include a first arc region I, a second arc region II, a third arc region III, and a fourth arc region IV. A plurality of first slots 107a may be disposed in the first arc region I. No slot(s) may be disposed in the second arc region II. A plurality of third slots 107c may be disposed in the third arc region III. No slot(s) may be disposed in the fourth arc region IV.

When the substrate (see W of FIG. 5) is loaded onto the lower electrode (see 102 of FIG. 1), the first portion J1 of the substrate W may be loaded to correspond to the first arc region I of the baffle plate 106. The second portion J2 of the substrate W may be loaded to correspond to the second arc region II of the baffle plate 106. Because the first slots are disposed only in the first arc region I, the etching amount of the first portion J1 may be larger than the etching amount of the second portion J2. As a result, the etching amounts of the first portion J1 and the second portion J2 may be adjusted uniformly.

Although the slots 107a and 107c are shown as being disposed only in the first arc region I and the third arc region III in FIGS. 20 and 21, the embodiment of the present disclosure is not limited thereto. As another example, the slots may also be disposed in the second arc region II and the fourth arc region IV. In this case, the aperture ratio of the slots disposed in the second arc region II may be smaller than the aperture ratio of the first slots 107a disposed in the first arc region I. The aperture ratio of the slots disposed in the fourth arc region IV may be smaller than the aperture ratio of the third slots 107c disposed in the third arc region III.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. An substrate processing apparatus comprising:
a chamber including a process space therein;
a lower electrode disposed inside the chamber;
an upper electrode structure disposed above the lower electrode to face the lower electrode; and
an annular baffle plate disposed to surround the process space,
wherein the annular baffle plate includes a first arc region and a second arc region which are disposed adjacent to each other along an annular arc and do not overlap each other,
the first arc region includes a plurality of first slots, and the second arc region includes a plurality of second slots, and
a first aperture ratio occupied by the first slots in the first arc region is different from a second aperture ratio occupied by the second slots in the second arc region.

2. The substrate processing apparatus of claim 1, further comprising:
a third arc region that faces the first arc region, and a fourth arc region that faces the second arc region, on the basis of a center of the annular arc.

3. The substrate processing apparatus of claim 2,
wherein a first central angle of the first arc region is greater than a second central angle of the second arc region,
a third central angle of the third arc region is the same as the first central angle,
a fourth central angle of the fourth arc region is the same as the second central angle,
the aperture ratio of the first arc region is the same as the aperture ratio of the third arc region,
the aperture ratio of the second arc region is the same as the aperture ratio of the fourth arc region, and
the aperture ratio of the first arc region is greater than the aperture ratio of the second arc region.

4. The substrate processing apparatus of claim 2,
wherein the third arc region includes a plurality of third slots, and the fourth arc region includes a plurality of fourth slots,
an third aperture ratio occupied by the third slots in the third arc region is the same as the first aperture ratio, and
a fourth aperture ratio occupied by the fourth slots in the fourth arc region is the same as the second aperture ratio.

5. The substrate processing apparatus of claim 4,
wherein the number of the first slots is the same as the number of the third slots,
the number of the second slots is the same as the number of the fourth slots, and
the number of the first slots is larger than the number of the second slots.

6. The substrate processing apparatus of claim 2,
wherein the third arc region includes a plurality of third slots, and the fourth arc region includes a plurality of fourth slots,
a region occupied by the first arc region and the third arc region in the annular baffle plate is greater than a region occupied by the second arc region and the fourth arc region in the annular baffle plate, and
a sum of the first aperture ratio and a third aperture ratio occupied by the third slots in the third arc region is greater than a sum of the second aperture ratio and a fourth aperture ratio occupied by the fourth slots in the fourth arc region.

7. The substrate processing apparatus of claim 1,
wherein the first arc region is greater than the second arc region, and the first aperture ratio is greater than the second aperture ratio.

8. The substrate processing apparatus of claim 1,
wherein the number of the first slots is different from the number of the second slots.

9. The substrate processing apparatus of claim 1,
wherein the annular baffle plate includes an inner boundary line and an outer boundary line, and
a distance of the first slots from the inner boundary line is shorter than a distance of the second slots from the inner boundary line.

10. The substrate processing apparatus of claim 1,
wherein the annular baffle plate includes a shape in which an upper horizontal part, a vertical part, and a lower horizontal part are connected, and
the first arc region and the second arc region are disposed in the lower horizontal part.

11. The substrate processing apparatus of claim 1,
wherein the upper electrode structure includes an upper electrode and a shower head,
the shower head includes a first region having first gas holes, and a second region having second gas holes, and
the number of first gas holes is different from the number of second gas holes.

12. The substrate processing apparatus of claim 1,
wherein the upper electrode structure includes an upper electrode and a shower head,
the shower head includes a first region having first gas holes, and a second region having second gas holes, and
the size of the first gas holes is different from the size of the second gas holes.

13. The substrate processing apparatus of claim 1,
wherein a first central angle of the first arc region is greater than a second central angle of the second arc region, and
the aperture ratio of the first arc region is greater than the aperture ratio of the second arc region.

14. A substrate processing apparatus comprising:
a chamber including a process space therein;
a lower electrode disposed inside the chamber;
an upper electrode structure disposed above the lower electrode to face the lower electrode; and
an annular baffle plate disposed to surround the process space,
wherein the annular baffle plate includes a first arc region and a second arc region which are disposed adjacent to each other along an annular arc and do not overlap each other,
the first arc region includes a plurality of slots, and the second arc region includes no slots.

15. The substrate processing apparatus of claim 14,
wherein the annular baffle plate includes a shape in which an upper horizontal part, a vertical part, and a lower horizontal part are connected, and
the first arc region and the second arc region are disposed in the lower horizontal part.

16. The substrate processing apparatus of claim 14,
wherein the first arc region is greater than the second arc region.

17. The substrate processing apparatus of claim 14,
wherein the upper electrode structure includes an upper electrode and a shower head,
the shower head includes a first region having first gas holes, and a second region having second gas holes, and
the number of first gas holes is different from the number of second gas holes.

18. The substrate processing apparatus of claim 14,
wherein the upper electrode structure includes an upper electrode and a shower head,
the shower head includes a first region having first gas holes, and a second region having second gas holes, and
the size of the first gas holes is different from the size of the second gas holes.

19. The substrate processing apparatus of claim 14, further comprising:
a third arc region that faces the first arc region, and a fourth arc region that faces the second arc region, on the basis of the center of the annular arc,
wherein a first central angle of the first arc region is greater than a second central angle of the second arc region,
a third central angle of the third arc region is the same as the first central angle, and
a fourth central angle of the fourth arc region is the same as the second central angle.

20. A substrate processing apparatus comprising:
a chamber including a process space therein;
a lower electrode disposed inside the chamber;
an upper electrode structure which is disposed above the lower electrode to face the lower electrode, and includes an upper electrode and a shower head; and
an annular baffle plate disposed to surround the process space,
wherein the shower head includes a first region having first gas holes, and a second region having second gas holes,
the number of first gas holes is different from the number of second gas holes,
the annular baffle plate has a shape in which an upper horizontal part, a vertical part, and a lower horizontal part are connected,
the lower horizontal part includes a first arc region and a second arc region which are disposed adjacent to each other along an annular arc and do not overlap each other,
the first arc region is greater than the second arc region,
the first arc region includes a plurality of first slots,
the second arc region includes a plurality of second slots, and
a first aperture ratio occupied by the first slots in the first arc region is greater than a second aperture ratio occupied by the second slots in the second arc region.
